(19) United States
(12) Patent Application Publication
(10) Pub. No.: US 2010/0000595 A1
(43) Pub. Date: Jan. 7, 2010

(54) SOLAR CELL MODULE

(75) Inventors: Takahiro HAGA, Osaka (JP); Shingo Okamoto, Osaka (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi City (JP)

(21) Appl. No.: 12/496,829

(22) Filed: Jul. 2, 2009

(30) Foreign Application Priority Data
Jul. 4, 2008 (JP) 2008-175972

(51) Int. Cl. H01L 31/052

(52) U.S. Cl. 136/246

(57) ABSTRACT

A solar cell module includes: solar cells; wiring members electrically connecting the solar cells to each other; and a reflecting plate disposed between a light receiving surface side protection member and the solar cells. Each of the wiring members has a connecting portion connected to a light receiving surface of each of the solar cells. The reflecting plate is disposed over connecting portions 11a of the wiring members 11. A top surface of the reflecting plate has light reflectivity.

### CROSS REFERENCE TO RELATED APPLICATIONS

This application is based upon and claims the benefit of priority from prior Japanese Patent Application No. 2008-175972, filmed on Jul. 4, 2008; the entire contents of which are incorporated herein by reference.

### BACKGROUND OF THE INVENTION

1. Field of the Invention

The present invention relates to a solar cell module including solar cells connected to each other by wiring members.

2. Description of the Related Art

A Solar cell directly converts clean and unlimitedly supplied sunlight into electricity. Thus, the solar cells are expected as a new energy source.

Generally, the output of a single solar cell is about several watts. For this reason, in order to use such a solar cell as a power source for a house, a building, or the like, a solar cell module in which solar cells are connected to each other to increase the output is used.

The solar cell module includes solar cells which are sealed with a sealing member between a light receiving surface side protection member and a back surface side protection member.

The solar cells are arrayed in an array direction and electrically connected to each other by wiring members. Specifically, each of the wiring members is connected to a light receiving surface of one solar cell and to a back surface of a different solar cell adjacent to the one solar cell.

Here, for the purpose of reducing optical loss caused by a surface of the wiring member, formation of asperities in the surface of the wiring member has been proposed (see specification of US Patent Application Publication No. 2007/0125415). Specifically, incident light toward the wiring member is reflected by the asperities formed in the surface of the wiring member, reflected once more by the interface between the light receiving surface side protection member and the atmosphere, and then guided to the solar cells.

In a manufacturing process of the solar cell module, the above-described wiring member is usually formed by cutting a long metal wire to a predetermined length, the metal wire having asperities formed entirely in one-side surface. However, a problem arises when such a wiring member is connected to the light receiving surface of the one solar cell and to the back surface of the other solar cell. That is, the adhesion between the back surface of the other solar cell and the wiring member is lowered because the asperities are formed in the one-side surface of the wiring member facing the back surface of the other solar cell.

In addition, in the manufacturing process of the solar cell, it is troublesome to form the asperities only in a portion of the wiring member that faces the light receiving surface side protection member, in other words, in the surface of a portion of the wiring member that is disposed on the light receiving surface of the one solar cell.

### SUMMARY OF THE INVENTION

The present invention is made in view of the above-described circumstances. An object of the present invention is to provide a solar cell module having a reduced optical loss caused by a surface of a wiring member while maintaining excellent adhesion between the wiring member and a solar cell.

A solar cell module according to an aspect of the present invention includes: first to third solar cells which are arrayed in an array direction between a light receiving surface side protection member and a back surface side protection member, and each of which has a light receiving surface and a back surface provided on a side opposite to the light receiving surface; a first wiring member connected to the light receiving surface of the first solar cell and to the back surface of the second solar cell; a second wiring member connected to the light receiving surface of the second solar cell and to the back surface of the third solar cell; and a reflecting plate disposed in the array direction between the light receiving surface side protection member and the first to third solar cells. The first wiring member has a first connecting portion disposed in the array direction and connected to the light receiving surface of the first solar cell, the second wiring member has a second connecting portion disposed in the array direction and connected to the light receiving surface of the second solar cell, the reflecting plate is disposed over the first and second connecting portions, and a surface of the reflecting plate that faces the light receiving surface side protection member has a light reflectivity.

According to the aspect of the present invention, a surface of the reflecting plate that faces the first and second connecting portions may have an insulating property.

According to the aspect of the present invention, the reflecting plate may include: a first conductive portion disposed on the first connecting portion; a second conductive portion disposed on the second connecting portion: and an insulating portion communicating with the first and second conductive portions.

A solar cell module according to a different aspect of the present invention includes: first and second solar cells which are arrayed in an array direction between a light receiving surface side protection member and a back surface side protection member, and each of which has a light receiving surface and a back surface provided on a side opposite to the light receiving surface; a wiring member connected to the light receiving surface of the first solar cell and to the light receiving surface of the second solar cell; and a reflecting plate disposed in the array direction between the light receiving surface side protection member and the first and second solar cells. The reflecting plate is disposed on the wiring member, and a surface of the reflecting plate that faces the light receiving surface side protection member has a light reflectivity.

According to the different aspect of the present invention, the reflecting plate is made of a conductive material.

The present invention can provide a solar cell module having a reduced optical loss caused by a surface of a wiring member while maintaining excellent adhesion between the wiring member and a solar cell maintained.

### BRIEF DESCRIPTION OF THE DRAWINGS

FIG. 1 is a side view of a solar cell module 100 according to a first embodiment of the present invention.

FIGS. 2A and 2B are plan views of solar cells 10 according to the first embodiment of the present invention.

FIG. 3 is an enlarged side view of a solar cell string 1 according to the first embodiment of the present invention.

FIG. 4 is a plan view of the solar cell string 1 according to the first embodiment of the present invention, the solar cell string 1 viewed from a light receiving surface side.

FIG. 5 is an enlarged side view of a solar cell string 1 according to a second embodiment of the present invention.

FIG. 6 is a plan view of the solar cell string 1 according to the second embodiment of the present invention, is the solar cell string 1 viewed from a light receiving surface side.

FIG. 7 is an enlarged side view of a solar cell string according to a third embodiment of the present invention.

FIGS. 8A and 8B are enlarged side views of solar cell strings according to the embodiment of the present invention.

### DETAILED DESCRIPTION OF THE INVENTION

Next, embodiments of the present invention will be described by using the drawings. In the following descriptions of the drawings, identical or similar constituents are denoted by identical or similar reference numerals. However, it is to be noted that the drawings are merely schematic and proportions of dimensions, for example, are different from actuality. Therefore, concrete dimensions, for example, should be determined in consideration of the following description. Moreover, dimensional relations and proportions may naturally be different among the drawings in same parts.

### First Embodiment

(Configuration of Solar Cell Module)

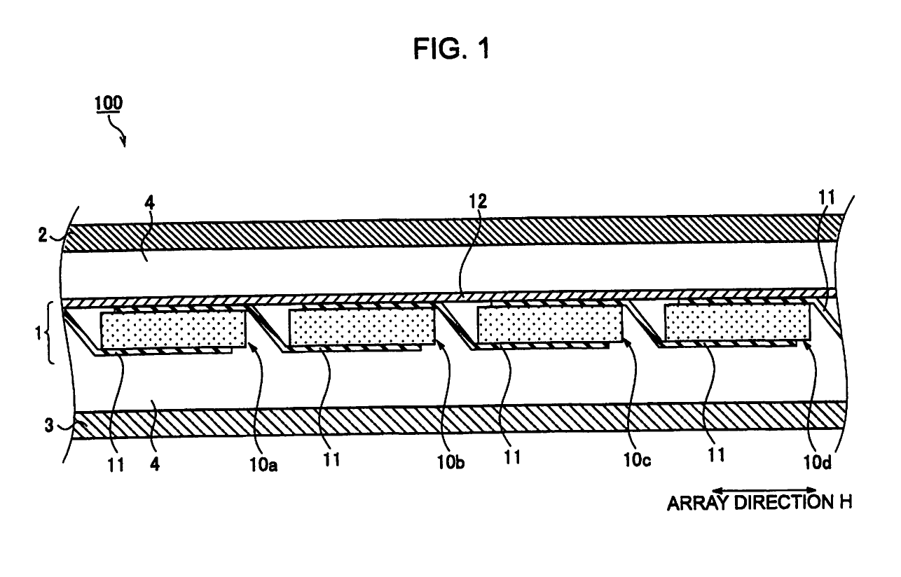

A schematic configuration of a solar cell module 100 according to a first embodiment of the present invention will be described with reference to FIG. 1. FIG. 1 is a side view of the solar cell module 100 according to the first embodiment.

The solar cell module 100 includes a solar cell string 1, a light receiving surface side protection member 2, a back surface side protection member 3, and a sealing member 4.

The solar cell string 1 is sealed between the light receiving surface side protection member 2 and the back surface side protection member 3 with the sealing member 4. The solar cell string 1 includes solar cells 10 (solar cells 10a to 10c), wiring members 11, and a reflecting plate 12.

The solar cells 10 are electrically connected to each other by the wiring members 11. The reflecting plate 12 is disposed between the light receiving surface side protection member 2 and the solar cells 10. Specifically, the reflecting plate 12 is disposed on the wiring members 11. The configuration of the solar cell string 1 will be described later in detail.

Each of the solar cells 10 has a light receiving surface that faces the light receiving surface side protection member 2, and a back surface that is provided on a side opposite to the light receiving surface and faces the back surface side protection member 3. The solar cells 10 are arrayed in an array direction H. The configuration of each of the solar cells 10 will be described later in detail.

The light receiving surface side protection member 2 is disposed on a light receiving surface side of each of the solar cells 10, and protects the front surface of the solar cell module 100. For the light receiving surface side protection member 2, a translucent and water-shielding glass, a translucent plastic, or the like may be used.

The back surface side protection member 3 is disposed on a back surface side of each of the solar cells 10, and protects the back surface of the solar cell module 100. For the back surface side protection member 3, a resin film made of polyethylene terephthalate (PET) or the like, or a stacked film having such a structure that a metal foil such as an Al foil or the like is sandwiched by resin films may be used, for example.

The sealing member 4 seals the solar cell string 1 between the light receiving surface side protection member 2 and the back surface side protection member 3. For the sealing member 4, a translucent resin such as EVA, EEA, PVB, silicone, urethane, acrylic, epoxy, or the like may be used.

In addition, an Al frame (unillustrated) may be attached to the periphery of the solar cell module 100 having the above-described configuration.

(Configuration of Solar Cell)

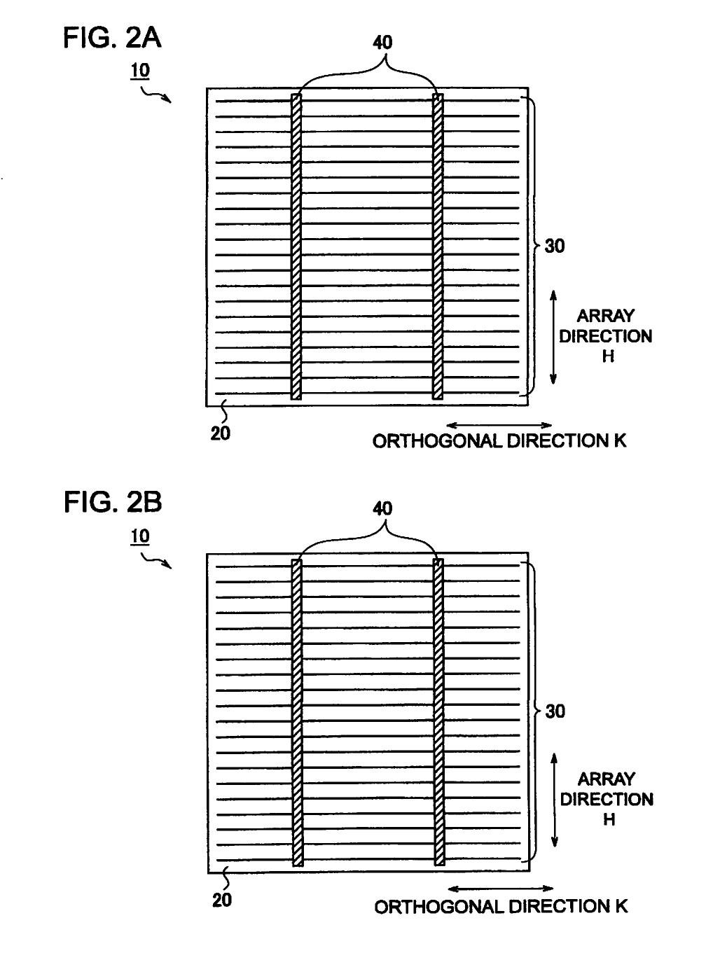

The configuration of the solar call 10 according to the first embodiment will be described below with reference to the drawings. FIG. 2A is a plan view of the solar cell 10 viewed from the light receiving surface side. FIG. 2B is a plan view of the solar cell 10 viewed from the back surface side.

As shown in FIGS. 2A and 2B, the solar cell 10 includes a photoelectric conversion part 20, thin line-shaped electrodes 30, and connecting electrodes 40. The thin line-shaped electrodes 30 and connecting electrodes 40 are formed in a comb shape similarly on both the light receiving surface and the back surface of the solar cell 10.

The photoelectric conversion part 20 generates photo-generated carriers by receiving light. The photo-generated carriers are holes and electrons generated when the photoelectric conversion part 20 absorbs solar light. The photoelectric conversion part 20 is provided inside with a semiconductor junction such as a pn junction, pin junction, or the like. The photoelectric conversion part 20 can be formed by using a general semiconductor material. Examples of such a semiconductor material include: a crystalline semiconductor material, such as a monocrystalline Si or a polycrystalline Si: a compound semiconductor material, such as GaAs or InP; and the like.

The thin line-shaped electrodes 30 are collecting electrodes collecting carriers from the photoelectric conversion part 20. Each of the thin line-shaped electrodes 30 is formed on the photoelectric conversion part 20 so as to extend in an orthogonal direction K approximately orthogonal to the array direction H. Each of the thin line-shaped electrodes 30 can be made of, for example, a resin conductive paste, a sintered conductive paste (i.e., ceramic paste), or the like. Note that the size and the number of the thin line-shaped electrodes 30 can be set as appropriate in consideration of the size and the properties of the photoelectric conversion part 20. For example, in a case where the photoelectric conversion part 20 has a size of approximately 100 mm square, approximately 50 thin line-shaped electrodes 30 can be formed. In addition, on the back surface of the solar cell 10, a collecting electrode covering the entire back surface may be formed instead of the thin line-shaped electrodes 30.

The connecting electrodes 40 are connected to the wiring members 11. The connecting electrodes 40 are formed on the photoelectric conversion part 20 so as to extend in the array directions. The connecting electrodes 40 can be made of a resin conductive paste, a sintered conductive paste (ceramic paste), or the like. Note that the size and the number of the connecting electrodes 40 can be set as appropriate in consideration of the size and the properties of the photoelectric conversion part 20. For example, in a case where the photoelectric conversion part 20 has a size of approximately 100 mm square, two connecting electrodes 40 each having a width of approximately 1.5 mm can be formed.

(Configuration of Solar Cell String)

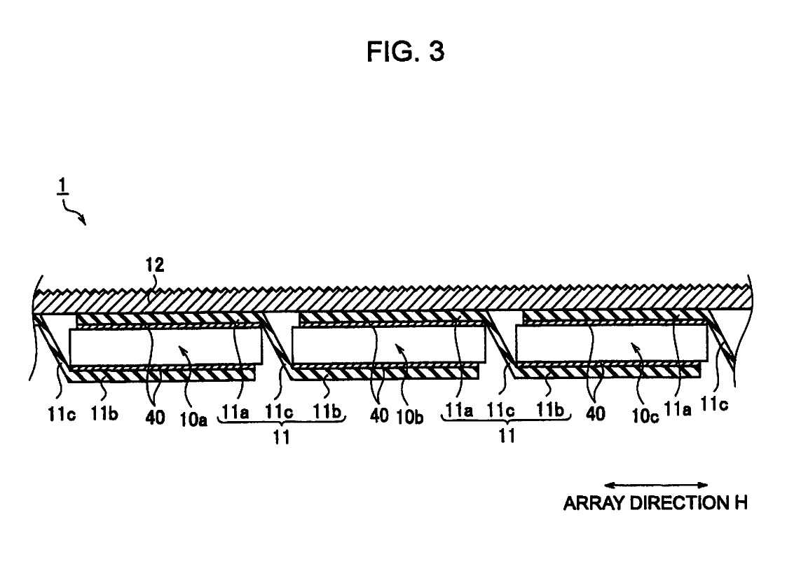

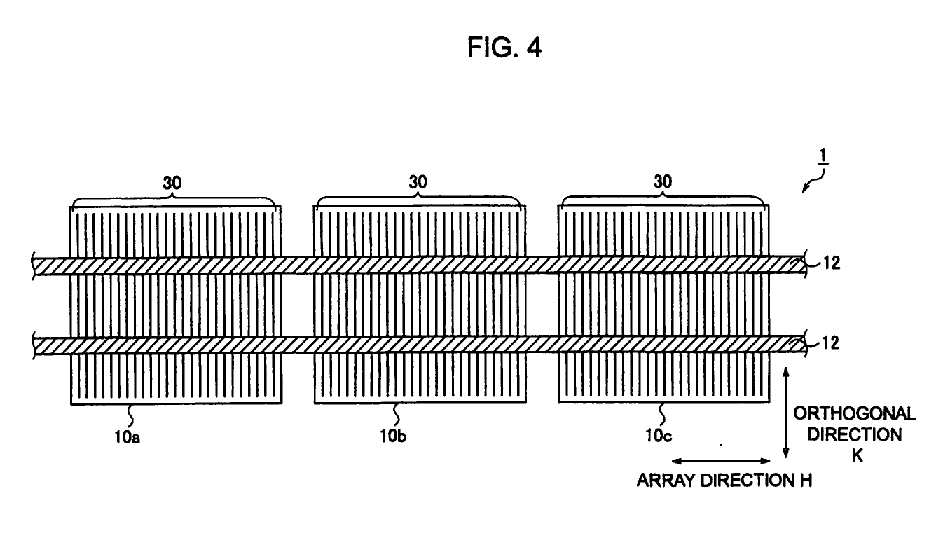

The configuration of the solar cell string 1 according to the first embodiment will be described below with reference to the drawings. FIG. 3 is an enlarged side view of the solar cell string 1. FIG. 4 is a plan view of the solar cell string 1 viewed from the light receiving surface side.

As shown in FIG. 3, each of the wiring members 11 electrically connects one solar cell 10 and a different solar cell 10 adjacent to the one solar cell 10. Specifically, the wiring members 11 extend in the array direction H and are connected to the connecting electrode 40 formed on the light receiving surface of the one solar cell 10 and to the connecting electrode 40 formed on the back surface of the different solar cell 10.

Specifically, each of the wiring members 11 has: a connecting portion 11a, a connecting portion 11b, and a communicating portion 11c. The connecting portion 11a is a portion of the wiring member 11 that is connected to the light receiving surface of the one solar cell 10. The connecting portion 11b is a portion of the wiring member 11 that is connected to the back surface of the different solar cell 10. The communicating portion 11c is a portion of the wiring member 11 that communicates with the connecting portion 11a and the connecting portion 11b.

Note that the light receiving surface of the solar cell 10 according to the present embodiment has one polarity whereas the back surface thereof has the other polarity. Thus, the one solar cell 10 and the different solar cell 10 are electrically connected to each other in series by the wiring members 11.

Each of the wiring members 11 is made of a low resistance element and a conductive material covering a surface of the low resistance element. For the low resistance element, a thin plate or a twisted wire made of copper, silver, gold, tin, nickel, aluminum, an alloy of any of these metals, or the like may be used. For the conductive material, lead-free solder plating, tin plating, or the like may be used.

Here, as shown in FIG. 3, the reflecting plate 12 is disposed over connecting portions 11a of each of the wiring members 11. Note that, the reflecting plate 12 is bonded to the connecting portions 11a by use of a resin adhesive or the like, although such bonding is not illustrated in the drawing. Thus, as shown in FIG. 4, the reflecting plate 12 is disposed over the solar cells 10 so as to extend in the array direction H, in a plan view seen from the light receiving surface side of the solar cell string 1.

The reflecting plate 12 is made of a conductive metal material, an insulating inorganic material, a resin material, or the like. Here, a surface of the reflecting plate 12 that faces the connecting portions 11a provides electrical isolation. This structure suppresses occurrences of electrical short circuits between the solar cells 10. Additionally, it is preferable that the reflecting plate 12 is made of an insulating material, but in a case where the reflecting plate 12 is made of a conductive material, it is preferable that the surface of the reflecting plate 12 that faces the connecting portions 11a is subjected to an insulation process, or that the reflecting plate 12 is bonded to the connecting portions 11a by use of an insulative adhesive so that the reflecting plate 12 can be electrically separated from the connecting portions 11a.

In addition, a surface (a top surface) of the reflecting plate 12 that faces the light receiving surface side protection member 2 has light reflectivity. Specifically, as shown in FIG. 3, multiple asperities are formed entirely in the top surface of the reflecting plate 12. This structure allows reflection (including scattering) of incident light toward each of the reflecting plate 12 (toward the wiring members 11) by the surfaces of the respective asperities. The light reflected by the surfaces of the respective asperities is reflected again at the interface between the light receiving surface side protection member 2 and the atmosphere, and then enters the photoelectric conversion part 20. Note that the base angles of each of the convex portions of the asperities formed in the top surface of the reflecting plate 12 is preferably determined so that light reflected by the surface of the convex portion would be totally reflected at the interface between the light receiving surface side protection member 2 and the atmosphere.

In addition, as long as the top surface of the reflecting plate 12 has light reflectivity, that is, light scattering properties, the formation of the multiple asperities is not necessary. For example, light incident upon the reflecting plate 12 may be scattered by using a white material to form the reflecting plate 12 or by painting the top surface of the reflecting plate 12 in white.

(Advantageous Effects)

The solar cell module 100 according to the first embodiment includes: the solar cells 10; the wiring members 11 electrically connecting the solar cells 10 to each other; and the reflecting plate 12 disposed between the light receiving surface side protection member 2 and the solar cells 10. The wiring members 11 have the connecting portions 11a connected to the light receiving surface of each of the solar cells 10. The reflecting plate 12 is disposed over the connecting portions 11a of the wiring members 11. The top surface of the reflecting plate 12 has light reflectivity.

In this way, incident light toward each of the wiring members 11 is reflected sequentially by the reflecting plate 12 and the light receiving surface side protection member 2, and then guided to the photoelectric conversion part 20. By making use of the light incident upon the surface of each of the wiring members 11, the photoelectric conversion efficiency of each of the solar cells 10 can be improved.

In addition, there is no need to perform a process to form asperities on the wiring members 11, or the like, thus preventing lowering the adhesion between each of the wiring members 11 and the corresponding solar cell 10 (the connecting electrode 40).

Moreover, the reflecting plate 12 can be disposed on the solar cells 10 with the resin adhesive interposed therebetween, the solar cells 10 connected to each other by the wiring members 11. Thus, the reflecting plate 12 can be easily attached in the manufacturing process of the solar cell module 100.

Furthermore, the surface of the reflecting plate 12 that faces the connecting portion 11a and the connecting portion 11b of the respective wiring members 11 has insulating properties, thereby suppressing occurrences of short circuits between the solar cells 10 even when the reflecting plate 12 is made of a conductive material. Specifically, the occurrences of short circuits between the solar cells 10 can be suppressed by performing an insulation process on the surface of the reflecting plate 12 that faces the connecting portions 11a, or by bonding the reflecting plate 12 and the connecting portions 11a together by use of an insulative adhesive.

### Second Embodiment

A second embodiment will be described below with reference to the drawings, Descriptions will be provided below mainly for the differences between the first embodiment described above and the second embodiment.

Specifically, in the second embodiment, the reflecting plate 12 has multiple conductive portions disposed respectively on connecting portions 11a of the wiring members 11, and multiple insulating portions each communicating with a pair of adjacent conductive portions.

(Configuration of Solar Cell String)

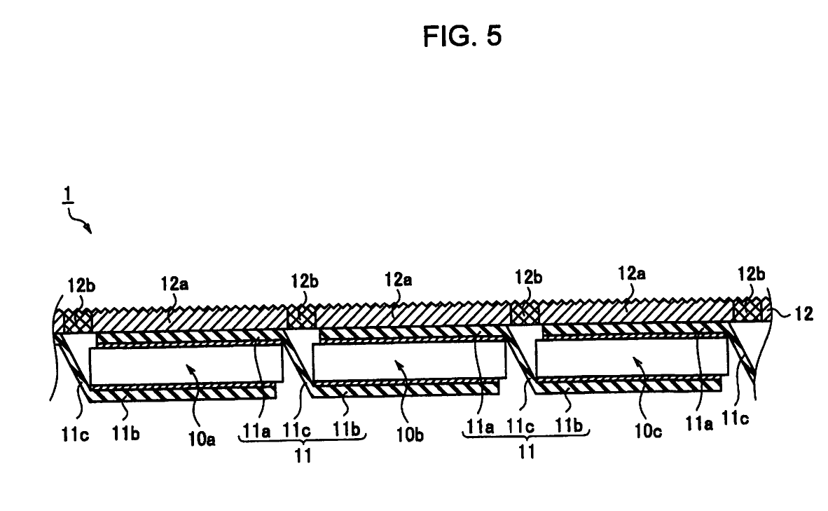

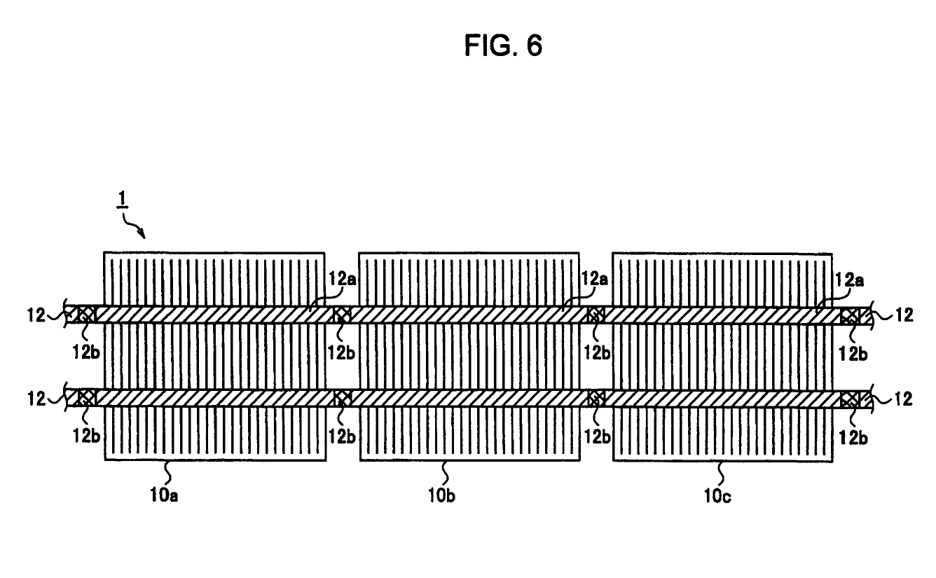

The configuration of a solar cell string 1 according to the second embodiment will be described below with reference to the drawings. FIG. 5 is an enlarged side view of the solar cell string 1. FIG. 6 is a plan view of the solar cell string 1 viewed from the light receiving surface side.

As shown in FIG. 5 and FIG. 6, the reflecting plate 12 has conductive portions 12a disposed respectively on connecting portions 11a of the wiring members 11, and insulating portions 12b communicating with a pair of adjacent conductive portions 12a.

Each of the conductive portions 12a is made of a conductive material such as metal. No insulation process is performed on the surfaces of the reflecting plate 12 according to the present embodiment, and thus the conductive portions 12a and the respective connecting portions 11a are electrically connected to each other.

Each insulating portion 12b is made of a known insulating material, and electrically separates the pair of the adjacent conductive portions 12a. Note that the conductive portions 12a and the insulating portions 12b are formed integrally. In addition, a surface of the conductive portions 12a and the insulating portions 12b that face a light receiving surface side protection member 2 has light reflectivity.

(Advantageous Effects)

The reflecting plate 12 according to the second embodiment has the conductive portions 12a and the insulating portions 12b each communicating with the pair of the adjacent conductive portions 12a.

Accordingly, occurrences of short circuits between solar cells 10 can be suppressed without performing an insulation process on the surfaces of the reflecting plate 12 that face the connecting portions 11a of the wiring members 11.

In addition, the conductive portions 12a are electrically connected to the connecting portions 11a, and thus function as part of the wiring members 11, respectively. It is therefore possible to reduce the inner electrical resistance of the wiring members 11.

Moreover, since the conductive portions 12a and the insulating portions 12b are formed integrally, the reflecting plate 12 can be easily disposed in the manufacturing process of the solar cell module 100.

### Third Embodiment

A third embodiment will be described below with reference to the drawings. Descriptions will be provided below mainly for the differences between the first embodiment described above and the third embodiment.

Specifically, in the third embodiment, the wiring members 11 are each connected to light receiving surfaces of a pair of adjacent solar cells 10, or connected to back surfaces of the solar cells 10.

(Configuration of Solar Cell String)

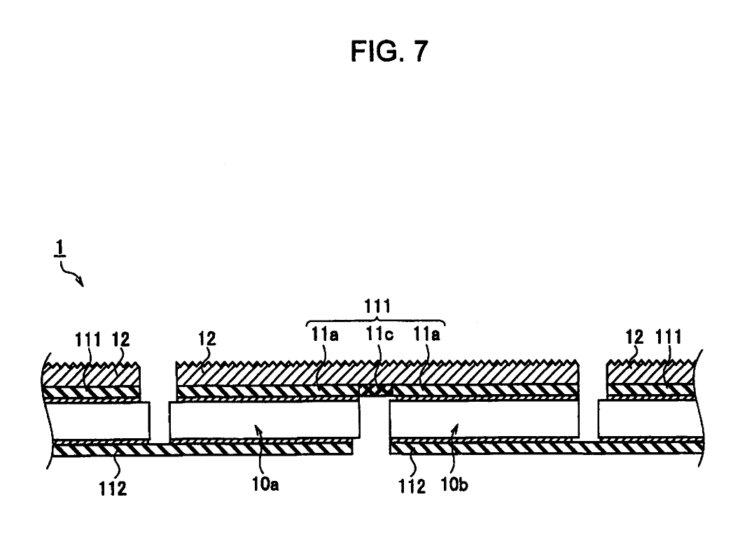

FIG. 7 is an enlarged side view of a solar cell string 1 according to the third embodiment. In the third embodiment, the wiring members 11 include: wiring members 111 each disposed on the light receiving surface sides of each of the solar cells 10: and wiring members 112 each disposed on the back surface sides of each of the solar cells 10.

As shown in FIG. 7, each of the wiring members 111 has: a pair of connecting portion 11a connected to a pair of the light receiving surface of the adjacent solar cells 10 (the solar cell 10a and the solar cell 10b); and a communicating portion 12c communicating with the pair of connecting portion 11a. Here, it should be noted that the pair of connecting portion 11a and the communicating portion 11c are integrally formed.

Each of the wiring members 112 is connected to a pair of the back surface of the adjacent solar cells 10.

Here, in the third embodiment, the polarity of the light receiving surface of the solar cell 10a is different from that of the light receiving surface of the solar cell 10b. The solar cell 10a is electrically connected to the solar cell 10b in series by one of the wiring members 111.

As shown in FIG. 7, each of reflecting plates 12 is disposed over the pair of the connecting portion 11a of the wiring members 111. In other words, each of the reflecting plates 12 according to the third embodiment is disposed on each of the wiring members 111 in an array direction. In addition, each of the reflecting plates 12 is made of a conductive material, such as metal, and electrically connected to each of the wiring members 111.

### Other Embodiments

Although the present invention has been described based on the above embodiments, it should not be understood that the statement and the drawings constituting part of this disclosure limit this invention. Various alternative embodiments, examples, and operation techniques become apparent to those skilled in the art from this disclosure.

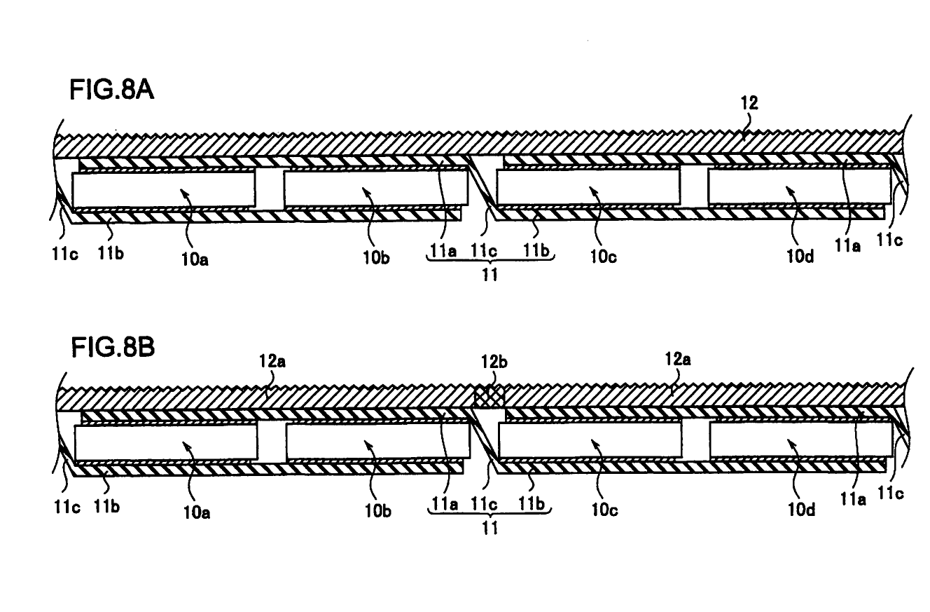

For example, in the above-described embodiments, the solar cells 10 are electrically connected to each other in series by the wiring members 11, but the configuration of the solar cell string 1 is not limited to this. As shown in FIGS. 8A and 8B, one wiring member 11 may connect the solar cell 10a and the solar cell 10b in parallel, connect the solar cell 10c and the solar cell 10d in parallel, and connect the parallel-connected solar cells 10a and 10b and the parallel-connected solar cells 10c and 10d in series.

To be more specific, as shown in FIG. 8A, each of the wiring members 11 has: a connecting portion 11a connected to the light receiving surfaces of the solar cell 10a and the solar cell 10b; a connecting portion 11b connected the back surfaces of the solar cell 10c and the solar cell 10d; and a communicating portion 11c communicating with the connecting portion 11a and the connecting portion 11b. The reflecting plate 12 is disposed over the connecting portions 11a of each of the wiring members 11.

In this case, it is preferable that a surface of the reflecting plate 12 that faces the connecting portions 11a should have insulating properties, but the configuration of the reflecting plate 12 is not limited to this. Specifically, as shown in FIG. 8B, the reflecting plate 12 may have conductive portions 12a disposed respectively on the connecting portions 11a, and insulating portions 12b each communicating with a pair of the adjacent conductive portions 12a.

The reflecting plate 12 is disposed on the connecting portions 11a in the above-described embodiments. However, if the solar cells 10 are bifacial-type solar cells, the reflecting plate 12 may be disposed over the connecting portions 11b as well. In other words, the reflecting plate 12 may also be disposed between the back surface side protection member 3 and the solar cells 10.

In addition, in the above-described embodiments, the thin line-shaped electrodes 30 and the connecting electrodes 40 are formed in the comb shape, but the configurations of the thin line-shaped electrodes 30 and the connecting electrodes 40 are not limited to this. For example, the wiring members 11 may be connected directly to the light receiving surfaces and the back surfaces of each of the solar cells 10 without forming the connecting electrodes 40 on the light receiving surfaces and the back surfaces.

Moreover, although it is not particularly mentioned in the above-described embodiments, there is no restriction on the configuration of the reflecting plate 12 as long as it is disposed over the solar cells 10. Further, the number of the solar cells 10 is not limited.

As described above, the present invention naturally includes various embodiments that are not described herein. Therefore, the technical scope of the present invention shall be determined solely by claimed elements according to the scope of claims reasonably understood from the above description.

What is claimed is:

1. A solar cell module comprising:
first to third solar cells which are arrayed in an array direction between a light receiving surface side protection member and a back surface side protection member, and each of which has a light receiving surface and a back surface provided on a side opposite to the light receiving surface;
a first wiring member connected to the light receiving surface of the first solar cell and to the back surface of the second solar cell;
a second wiring member connected to the light receiving surface of the second solar cell and to the back surf ace of the third solar cell; and
a reflecting plate disposed in the array direction between the light receiving surface side protection member and the first to third solar cells, wherein
the first wiring member has a first connecting portion disposed in the array direction and connected to the light receiving surface of the first solar cell,
the second wiring member has a second connecting portion disposed in the array direction and connected to the light receiving surface of the second solar cell,
the reflecting plate is disposed over the first and second connecting portions, and
a surface of the reflecting plate that faces the light receiving surface side protection member has a light reflectivity.

2. The solar cell module according to claim 1, wherein a surface of the reflecting plate that faces the first and second connecting portions has an insulating property.

3. The solar cell module according to claim 1, wherein
the reflecting plate includes:
a first conductive portion disposed on the first connecting portion;
a second conductive portion disposed on the second connecting portion; and
an insulating portion communicating with the first and second conductive portions.

4. A solar cell module comprising:
first and second solar cells which are arrayed in an array direction between a light receiving surface side protection member and a back surface side protection member, and each of which has a light receiving surface and a back surface provided on a side opposite to the light receiving surface;
a wiring member connected to the light receiving surface of the first solar cell and to the light receiving surface of the second solar cell; and
a reflecting plate disposed in the array direction between the light receiving surface side protection member and the first and second solar cells, wherein
the reflecting plate is disposed on the wiring member, and
a surface of the reflecting plate that faces the light receiving surface side protection member has a light reflectivity.

5. The solar cell module according to claim 4, wherein the reflecting plate is made of a conductive material.
